(19) United States
(12) Patent Application Publication
(10) Pub. No.: US 2022/0406643 A1
(43) Pub. Date: Dec. 22, 2022

(54) SEMITRANSPARENT SUBSTRATE SUPPORT FOR MICROWAVE DEGAS CHAMBER

(71) Applicant: Applied Materials, Inc., Santa Clara, CA (US)

(72) Inventors: Tuck Foong KOH, Singapore (SG); Prashant AGARWAL, Singapore (SG); Ananthkrishna JUPUDI, Singapore (SG)

(21) Appl. No.: 17/351,530

(22) Filed: Jun. 18, 2021

(51) Int. Cl. H01L 21/687; H01L 21/67; H05B 6/64

(52) U.S. Cl. CPC H01L 21/6875; H01L 21/67115; H01L 21/68757; H01L 21/68742; H05B 6/6402; H05B 6/6491

(57) ABSTRACT

Embodiments of substrate supports for use in microwave degas chambers are provided herein. In some embodiments, a substrate support for use in a microwave degas chamber includes a support plate having one or more support features for supporting a substrate; a susceptor comprising a plate disposed on the support plate, wherein the susceptor includes one or more openings, wherein the one or more support features extend through corresponding ones of the one or more openings; and a metal foil disposed beneath a side of the susceptor facing the support plate.

### FIELD

Embodiments of the present disclosure generally relate to a substrate processing equipment, and more specifically, to microwave degas chambers.

### BACKGROUND

In the processing of semiconductor substrates, or wafers, in the formation of integrated circuit structures thereon, substrates are often degassed between processes to remove adsorbed gases, moisture, etc. from the substrate prior to, for example, performing deposition or other processes on the substrate. If the absorbed gaseous impurities are not removed prior to subsequent processing, they may undesirably outgas during the process, leading to contamination, quality reduction, or the like. Conventional degas chambers use a heating element such as a hot plate or resistive heater. Microwave heat sources may be used to degas the substrates more quickly. However, conventional substrate supports may not provide adequate temperature uniformity when used with a microwave heat source.

Accordingly, the inventors have provided improved substrate supports for use in microwave degas chambers.

### SUMMARY

Embodiments of substrate supports for use in microwave degas chambers are provided herein. In some embodiments, a substrate support for use in a microwave degas chamber includes a support plate having one or more support features for supporting a substrate; a susceptor comprising a plate disposed on the support plate, wherein the susceptor includes one or more openings, wherein the one or more support features extend through corresponding ones of the one or more openings; and a metal foil disposed beneath a side of the susceptor facing the support plate.

In some embodiments, a substrate support for use in a microwave degas chamber includes: a support plate having one or more support features that are fixed to the support plate for supporting a substrate; a susceptor comprising a flat plate that is circular and disposed on the support plate, wherein the susceptor includes one or more openings corresponding with the one or more support features, and wherein the susceptor is made of a material having a thermal conductivity of about 190 watts per meter kelvin (W/mK) or greater; and a metal foil coupled to the susceptor on a side of the susceptor facing the support plate or a side of the support plate opposite the susceptor.

In some embodiments, a microwave degas chamber for processing a substrate includes: a chamber body having an interior volume; a support plate made of a first material disposed in the interior volume and having one or more support features for supporting the substrate; a susceptor comprising a plate made of a second material disposed on the support plate, wherein the susceptor includes one or more openings corresponding with the one or more support features; a microwave source coupled to the chamber body and configured to supply microwave radiation to heat the substrate; and a metal foil disposed between the susceptor and the microwave source.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic side view of a microwave degas chamber in accordance with at least some embodiments of the present disclosure.

FIG. 2 depicts a simplified schematic side view of a microwave degas chamber in accordance with at least some embodiments of the present disclosure.

FIG. 3 depicts a simplified schematic side view of a microwave degas chamber in accordance with at least some embodiments of the present disclosure.

FIG. 4 depicts an isometric view of a portion of a substrate support in accordance with at least some embodiments of the present disclosure.

FIG. 5 depicts an isometric view of a portion of a substrate support in accordance with at least some embodiments of the present disclosure.

FIG. 6 depicts an isometric view of a portion of a substrate support in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of substrate supports for use in a microwave degas chamber are provided herein. The substrate support generally includes a susceptor disposed on a support plate. The susceptor heats up by absorbing microwave radiation provided to the susceptor to heat a substrate disposed on or above the susceptor. A more uniform temperature profile across the susceptor provides more uniform heating to the substrate. In some embodiments, the susceptors disclosed herein are advantageously made of a material having a high thermal conductivity, for example, at least 200 W/mK to increase temperature uniformity of the susceptor. Metal is good at reflecting microwave radiation and therefore, in some embodiments, a metal plate or foil is disposed between the susceptor and a microwave source to advantageously disperse microwave radiation across the susceptor to increase temperature uniformity.

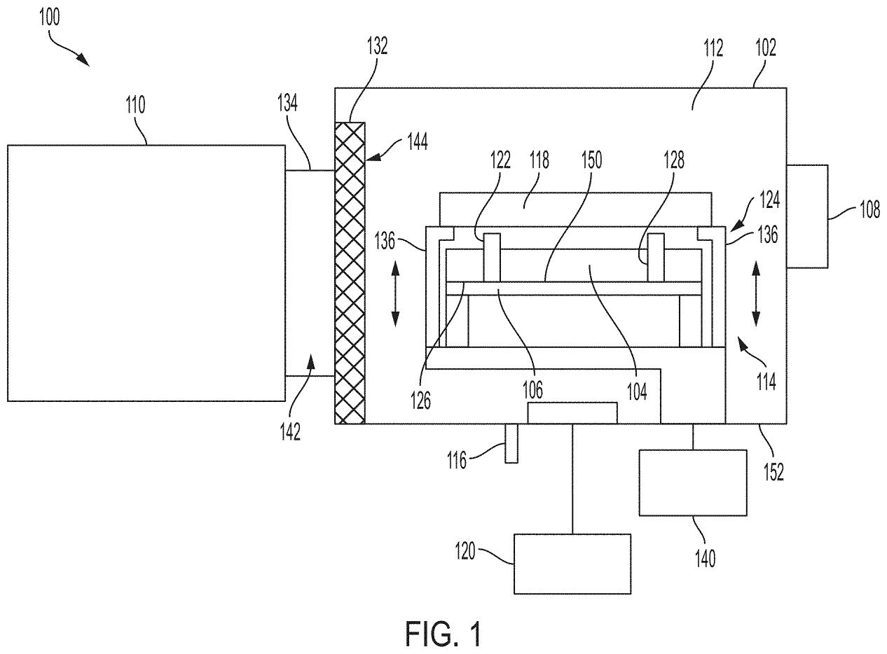

FIG. 1 depicts a schematic side view of a microwave degas chamber (e.g., chamber 100) in accordance with at least some embodiments in the present disclosure. The chamber 100 generally includes a chamber body 102 enclosing an interior volume 112. The chamber 100 may be a standalone chamber or part of a multi-chamber processing tool. A substrate support 124 is disposed in the interior volume 112 to support a substrate 118 when disposed on the substrate support 124.

A slit valve 108 is coupled to the chamber body 102 for transferring one or more substrates into or out of the chamber body 102 while also providing a selective seal. In some embodiments, the slit valve 108 can facilitate the transferring of one or more substrates between the chamber body 102 and a factory interface of a multi-chamber processing tool.

A microwave source 120 is coupled to the chamber body 102 and configured to supply microwave radiation to heat the substrate 118. For example, the microwave source 120 is configured to provide volumetric heating to the interior volume 112 to degas the substrate 118. In some embodiments, the microwave source provides microwaves to the chamber body 102 at a frequency range of about 5 to about 7 gigahertz.

The chamber body 102 includes a pump inlet 134, or exhaust port for exhausting degassed material from the interior volume 112. The pump inlet 134 is fluidly coupled to a pump 110. The pump 110 can be any pump suitable for evacuating degassed material from the interior volume 112. In some embodiments, a pump adapter 142 is disposed between the pump inlet 134 and the pump 110 to facilitate the coupling of various different pumps to the pump inlet 134. In some embodiments, the pump inlet 134 is disposed on a sidewall of the chamber body 102. However, in other embodiments, the pump inlet 134 may be disposed along a floor, or bottom, of the chamber body 102.

a pump coupled to the chamber body via a pump inlet and a mesh coupled to the chamber body at the pump inlet.

In some embodiments, a mesh 132 is coupled to the chamber body 102 at the pump inlet 134. The mesh 132 includes a plurality of openings 144 overlaying the pump inlet 134. The plurality of openings 144 are configured to reduce or eliminate microwave leakage through the pump inlet 134. The plurality of openings 144 may have a circular shape, a regular polygon shape, or any other suitable shape. In some embodiments, the plurality of openings 144 are sized to be less than one fourth of the given wavelength of the microwave source 120.

The substrate support 124 generally includes a support plate 106 and a susceptor 104 disposed on the support plate 106. The support plate 106 has one or More support features 122 fixed to the support plate 106 for supporting the substrate 118. In some embodiments, the one or more support features 122 include a plurality of pins that extend up from an upper surface 126 of the support plate 106 and through one or more openings 128 in the susceptor 104. In some embodiments, the one or more support features 122 extend above the susceptor 104 to support the substrate 118 above the susceptor 104. In some embodiments, the one or more support features 122 extend about 1 to about 4 mm above the susceptor 104.

The support plate 106 is made of a first material. The first material may be generally transparent to microwave radiation. In some embodiments, the first material consists essentially of a polymer material. In some embodiments, the polymer material consists essentially of polyether ether ketone.

The susceptor 104 comprises a flat plate made of a second material different than the first material. In some embodiments, the susceptor 104 is a circular plate. In some embodiments, the susceptor 104 includes one or more openings 128 corresponding with the one or more support features 122. In some embodiments, the support plate 106 is made of a material that is more transparent to MW radiation than the susceptor 104. In some embodiments, the susceptor 104 is made of a material having a thermal conductivity of about 190 watts per meter kelvin (W/mK) or greater to enhance temperature uniformity of the susceptor 104 when heated. In some embodiments, the susceptor 104 is made of or fabricated from silicon carbide (SiC).

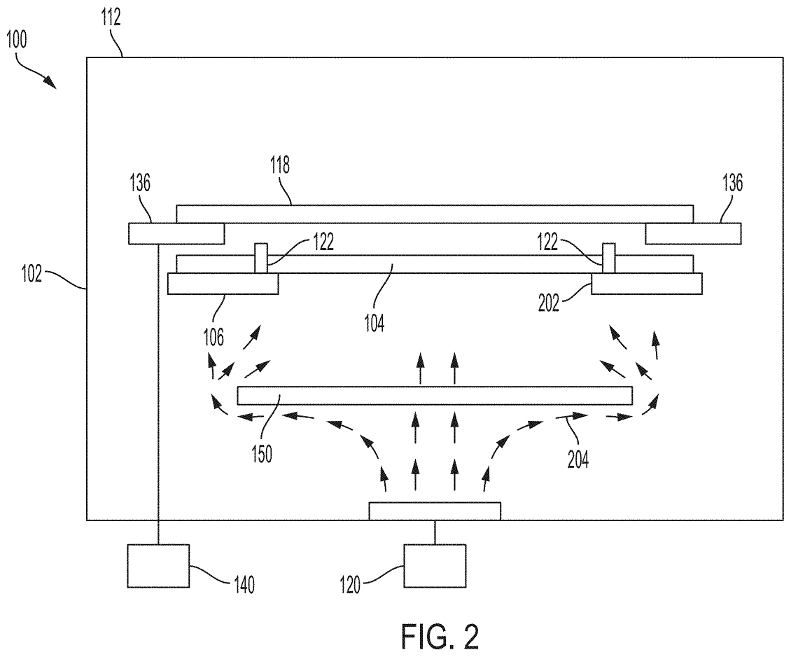

A metal foil 150 is disposed between the susceptor 104 and the microwave source 120. The metal foil 150, which reflects microwave radiation, advantageously disperses microwave radiation from the microwave source 120 to the susceptor 104, providing more uniform heating of the susceptor 104. In some embodiments, as shown in FIG. 1, the metal foil 150 is coupled to the susceptor 104 on a side of the susceptor 104 facing the support plate 106 (e.g., sandwiched between the susceptor 104 and the support plate 106). The metal foil 150 may alternatively be on a side of the support plate 106 opposite the susceptor 104. In some embodiments, the metal foil 150 is disposed between the susceptor 104 and the microwave source 120 without contacting the susceptor 104 (see FIG. 2). In some embodiments, the metal foil 150 is aluminum foil or copper foil.

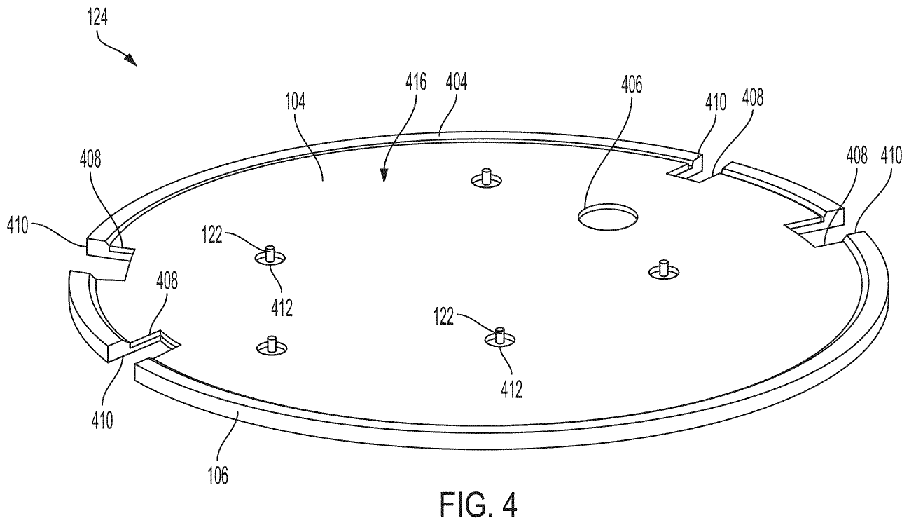

The chamber 100 includes a lift mechanism 114 having one or more lifters 136 and configured to selectively raise or lower the substrate 118 with respect to the susceptor 104. The lift mechanism 114 may align the substrate 118 with the slit valve 108 to facilitate transferring the substrate 118 into and out of the interior volume 112. The lift mechanism 114 includes an actuator 140 coupled to the one or more lifters 136 to facilitate moving the one or more lifters 136. In some embodiments, the one or more lifters 136 are disposed radially outward of the support plate 106 and the susceptor 104. In some embodiments, at least one of the support plate 106 or the susceptor 104 include one or more lift openings configured to accommodate the one or more lifters 136 therethrough (see FIG. 4).

In some embodiments, a temperature sensor 116 is coupled to the chamber body 102 and configured to take a temperature reading of the substrate 118. In some embodiments, the temperature sensor 116 is coupled to the floor 152 of the chamber body 102. In some embodiments, the temperature sensor 116 may be coupled to sidewalls of the chamber body 102.

In use, the lift mechanism 114 may raise the one or more lifters 136 to receive the substrate 118. The lift mechanism 114 may then lower the one or more lifters 136 to place the substrate 118 on the support plate 106. The microwave source 120 directs microwave radiation towards the susceptor 104 to heat the susceptor 104. Heat from the susceptor 104 heats the substrate 118 disposed above or on the susceptor 104 via radiative or conductive heat transfer to degas the substrate 118.

FIG. 2 depicts a simplified schematic side view of a microwave degas chamber in accordance with at least some embodiments in the present disclosure. In some embodiments, the support plate 106 is a ring (i.e., the support plate 106 has a central opening 202). In some embodiments, as shown in FIG. 2, the metal foil 150 is disposed between the susceptor 104 and the microwave source 120 without contacting the susceptor 104. The metal foil 150 is configured to reflect microwave radiation 204 from the microwave source 120. Some of the microwave radiation 204 passes through the metal foil 150, however, a majority of the microwave radiation 204 flows around the metal foil 150 to more uniformly heat the susceptor 104.

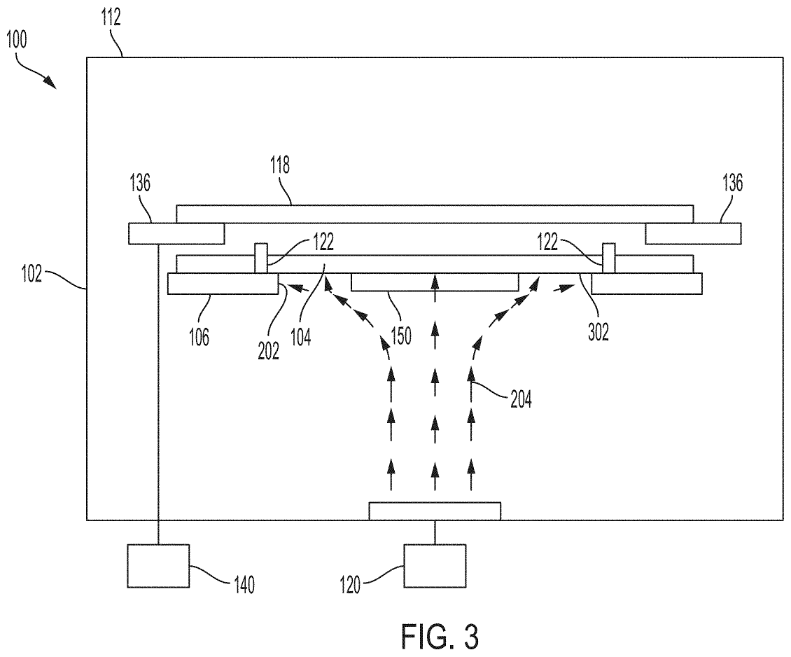

FIG. 3 depicts a simplified schematic side view of a microwave degas chamber in accordance with at least some embodiments in the present disclosure. In some embodiments, the metal foil 150 is coupled to a back surface 302 of the susceptor 104. In some embodiments, the metal foil 150 is coupled to a central portion of the susceptor 104 and has an outer diameter less than an outer diameter of the susceptor 104. In some embodiments, the metal foil 150 has an outer diameter less than diameter of the central opening 202.

FIG. 4 depicts an isometric top view of a portion of a substrate support 124 in accordance with at least some embodiments in the present disclosure. In some embodiments, the support plate 106 includes a raised outer lip 404 that is raised with respect to a central portion 416 of the support plate 106. In some embodiments, the susceptor 104 is disposed within the raised outer lip 404. In some embodiments, the susceptor 104 includes support openings 412 corresponding with the locations and the geometry of the one or more support features 122. In some embodiments, the one or more support features 122 are cylindrical pins. In some embodiments, the susceptor 104 includes a temperature sensor opening 406 aligned with the temperature sensor 116.

In some embodiments, the susceptor 104 includes one or more lift openings 408 for the one or more lifters 136. In some embodiments, the one or more lift openings 408 extend radially inward from an outer sidewall of the susceptor 104. In some embodiments, the support plate 106 includes one or more lift openings 410 for the one or more lifters 136. In some embodiments, the one or more lift openings 410 extend radially inward from an outer sidewall of the support plate 106. In some embodiments, the one or more lift openings 408 and the one or more lift openings 410 comprise two pairs of openings, or four openings. In some embodiments, the pairs of openings are disposed on opposite sides of the support plate 106 and the susceptor 104.

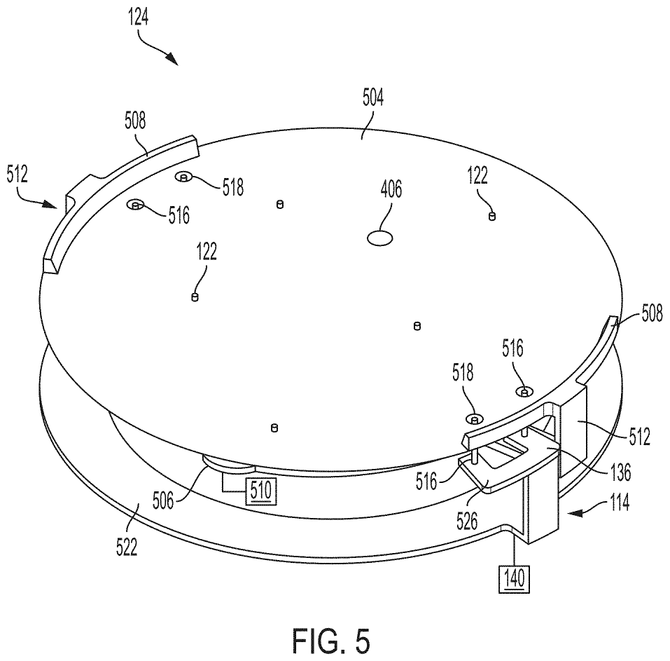

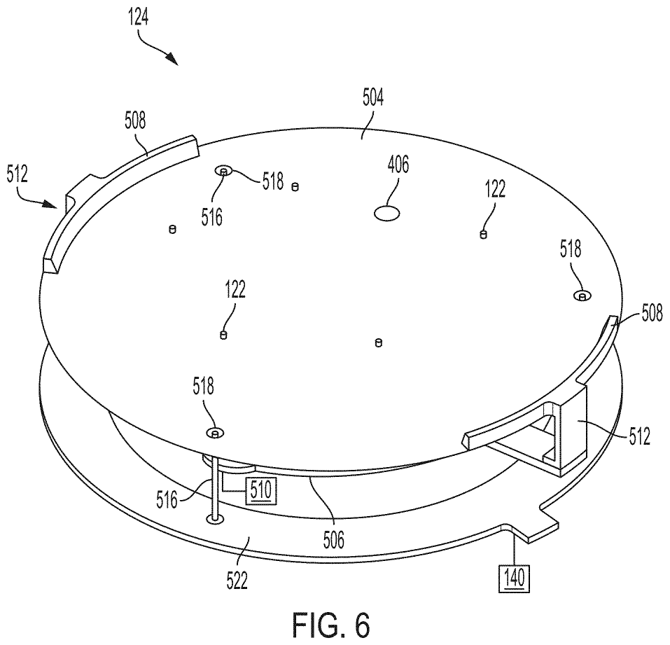

FIG. 5 depicts an isometric view of a portion of a substrate support in accordance with at least some embodiments of the present disclosure. FIG. 6 depicts an isometric view of a portion of a substrate support in accordance with at least some embodiments of the present disclosure. In some embodiments, as shown in FIGS. 5 and 6, the support plate 106 and the susceptor 104 comprise a single unitary body 504 to increase thermal uniformity. In some embodiments, the metal foil 150 is coupled to a lower surface of the single unitary body 504. The single unitary body 504 may include the one or more support features 122 formed with the single unitary body 504 or coupled to the single unitary body 504. In some embodiments, the single unitary body 504 is made of any materials discussed above with respect to the susceptor 104. In some embodiments, the one or more support features 122 are made of a same material as the single unitary body 504. In some embodiments, the one or more support features 122 are made of a material that is more transparent to microwave radiation than the material of the single unitary body 504.

In some embodiments, the single unitary body 504 include one or more substrate guides 508 (2 shown in FIGS. 5 and 6). In some embodiments, the one or more substrate guides 508 are arcuate raised lips along an outer periphery of the single unitary body 504 that support the substrate 118 at an edge of the substrate 118 and assist in preventing the substrate 118 from sliding off of the single unitary body 504. In some embodiments, the one or more substrate guides 508 may be a single annular raised lip along the outer periphery of the single unitary body 504. In some embodiments, the single unitary body 504 is coupled to one or more support arms 512 that are coupled to a support ring 506 disposed below the single unitary body 504. The support ring 506 may be coupled to a second actuator 510 for raising or lowering the single unitary body 504. In some embodiments, the one or more support arms 512 are disposed at locations corresponding with the one or more substrate guides 508.

In some embodiments, the one or more lifters 136 may be coupled to a lift ring 522 of the lift mechanism 114. In some embodiments, as shown in FIG. 5, the lift mechanism 114 comprises one or more lifters 136 having a base plate 526 and one or more lift pins 516 that extend from the base plate 526. In some embodiments, the base plate 526 has a U-shaped profile. In some embodiments, two lift pins extend from each of the base plates 526. The one or more lift pins 516 are configured to extend into corresponding lift pin openings 518 in the single unitary body 504 to selectively raise or lower the substrate 118 off of or onto the one or more support features. In some embodiments, an outer diameter of the lift ring 522 is greater than an outer diameter of the support ring 506. In some embodiments, the one or more lifters 136 include two lifters that are diametrically opposed.

In some embodiments, as shown in FIG. 6, the one or more lifters 136 comprise one or more lift pins 516 that are directly coupled to the lift ring 522 and configured to extend into the lift pin openings 518 of the single unitary body 504. In some embodiments, the lift pin openings 518 are uniformly disposed about the single unitary body 504. The one or more lift pins 516 may be made of a ceramic material or a material that is more transparent to microwave radiation than the material of the single unitary body 504. The lift mechanism 114 shown and described with respect to FIGS. 5 and 6 may be used with any of the embodiments disclosed herein.

While the foregoing is directed to embodiments of the present disclosure, other and further embodiments of the disclosure may be devised without departing from the basic scope thereof.

1. A substrate support for use in a microwave degas chamber, comprising:
a support plate having one or more support features for supporting a substrate;
a susceptor comprising a plate disposed on the support plate, wherein the susceptor includes one or more openings, wherein the one or more support features extend through corresponding ones of the one or more openings; and
a metal foil disposed beneath a side of the susceptor facing the support plate.

2. The substrate support of claim 1, wherein at least one of:
the metal foil is aluminum foil or copper foil, or
wherein the susceptor is fabricated from silicon carbide (SiC).

3. The substrate support of claim 1, wherein the metal foil is coupled to the susceptor or to the support plate.

4. The substrate support of claim 1, wherein the support plate is made of a material that is more transparent to MW radiation than the susceptor.

5. The substrate support of claim 1, wherein the susceptor is made of a material that has a thermal conductivity of about 190 watts per meter kelvin (W/mK) or greater.

6. The substrate support of claim 1, wherein the support plate and the susceptor comprise a single unitary body.

7. The substrate support of claim 1, wherein the support plate and the susceptor both include one or more lift openings configured to accommodate one or more lifters therethrough.

8. The substrate support of claim 1, wherein the metal foil is coupled to a central portion of the susceptor or a central portion of the support plate and has an outer diameter less than an outer diameter of the susceptor.

9. The substrate support of claim 1, further comprising a lift mechanism having one or more lifters that extend through corresponding lift openings of the susceptor and the support plate, wherein the lift mechanism is configured to selectively raise or lower the substrate with respect to the susceptor.

10. A substrate support for use in a microwave degas chamber, comprising:
a support plate having one or more support features that are fixed to the support plate for supporting a substrate;
a susceptor comprising a flat plate that is circular and disposed on the support plate, wherein the susceptor includes one or more openings corresponding with the one or more support features, and wherein the susceptor is made of a material having a thermal conductivity of about 190 watts per meter kelvin (W/mK) or greater; and
a metal foil coupled to the susceptor on a side of the susceptor facing the support plate or a side of the support plate opposite the susceptor.

11. The substrate support of claim 10, wherein at least one of:
the support plate is made of a polymer material that consists essentially of polyether ether ketone, or
the susceptor is made of silicon carbide (SiC).

12. The substrate support of claim 10, wherein the one or more support features extend above the susceptor to support the substrate about 1 to about 4 mm above the susceptor.

13. The substrate support of claim 10, wherein the support plate and the susceptor comprise a unitary body made of a same material.

14. A microwave degas chamber for processing a substrate, comprising:
a chamber body having an interior volume;
a support plate made of a first material disposed in the interior volume and having one or more support features for supporting the substrate;
a susceptor comprising a plate made of a second material disposed on the support plate, wherein the susceptor includes one or more openings corresponding with the one or more support features;
a microwave source coupled to the chamber body and configured to supply microwave radiation to heat the substrate; and
a metal foil disposed between the susceptor and the microwave source.

15. The microwave degas chamber of claim 14, further comprising a temperature sensor coupled to the chamber body and configured to take a temperature reading of the substrate.

16. The microwave degas chamber of claim 14, further comprising a pump coupled to the chamber body via a pump inlet and a mesh coupled to the chamber body at the pump inlet.

17. The microwave degas chamber of claim 14, wherein the microwave source is configured to supply microwave radiation at a frequency of about 5 to about 7 gigahertz.

18. The microwave degas chamber of claim 14, wherein the one or more support features include one or more pins that extend from the support plate and through the one or more openings of the susceptor.

19. The microwave degas chamber of claim 14, wherein the first material is the same as the second material.

20. The microwave degas chamber of claim 14, wherein the support plate is made of a polymer material and the susceptor is made of silicon carbide (SiC).
